(19) United States
(12) Patent Application Publication
(10) Pub. No.: US 2012/0125945 A1
(43) Pub. Date: May 24, 2012

(54) SURFACE MOUNTING APPARATUS AND WINDER THEREOF

(75) Inventors: TSUNG-CHIH TSAI, Tu-Cheng (TW); CHAO-AN KANG, Tu-Cheng (TW); SHANG-YU LIN, Tu-Cheng (TW)

(73) Assignee: HON HAI PRECISION INDUSTRY CO., LTD., Tu-Cheng (TW)

(21) Appl. No.: 12/977,089

(22) Filed: Dec. 23, 2010

(30) Foreign Application Priority Data
Nov. 18, 2010 (TW) 99139649

(51) Int. Cl. H05K 13/02; H05K 13/00; B65H 18/08; B65H 5/28

(52) U.S. Cl. 221/69; 242/520

(57) ABSTRACT

An exemplary surface mounting apparatus includes a winder, a waste tape and a feeder for discharging the waste tape towards the winder. The winder includes a pivot, a wheel rotatably mounted around the pivot, and a coil spring disposed between the pivot and the wheel. An outer end of the coil spring is connected to the wheel to rotate with the wheel, and an inner end of the coil spring is static relative to the pivot during rotation of the wheel. The waste tape is connected to the wheel of the winder.

### BACKGROUND

1. Technical Field

The present disclosure relates to surface mounting apparatuses, and more particularly to winders of surface mounting apparatuses.

2. Description of Related Art

Surface mounting technology (SMT) has been widely used in recent years for mounting electric components on printed circuit boards. In a typical SMT process, while components are mounted on a series of printed circuit boards one by one, waste tape is progressively discharged. Generally, a winder is provided to wind the waste tape. However, the winder is usually driven by a motor, which can result in high energy consumption. In addition, a torque output of the motor may be unstable. When this happens, tension on the waste tape is unstable, and this in turn may result in bad contact when the components are mounted on the printed circuit boards.

What is needed, therefore, is a solution which can overcome the limitations described.

### BRIEF DESCRIPTION OF THE DRAWINGS

FIG. 1 is an isometric, assembled view of a surface mounting apparatus according to an exemplary embodiment of the present disclosure.

FIG. 2 is a partly exploded view of the surface mounting apparatus of FIG. 1.

FIG. 3 is another partly exploded view of the surface mounting apparatus of FIG. 1.

FIG. 4 is an enlarged cross section of a top winder of the surface mounting apparatus of FIG. 1, taken along a line IV-IV thereof.

### DETAILED DESCRIPTION

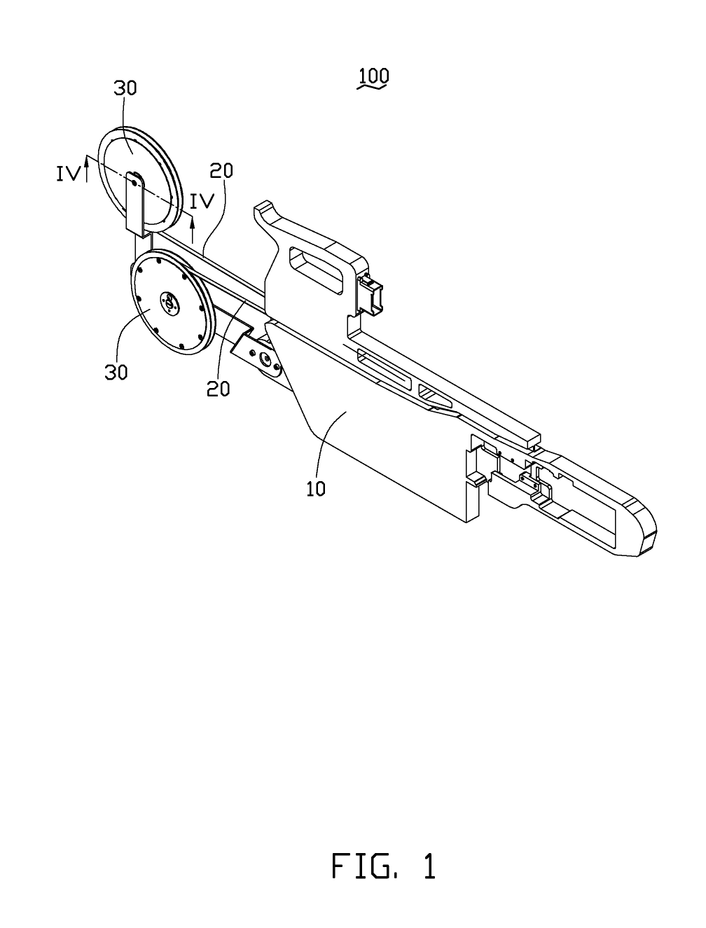

Referring to FIG. 1, a surface mounting apparatus 100 in accordance with an exemplary embodiment is shown. The surface mounting apparatus 100 includes a feeder 10, two waste tapes 20 and two winders 30. The feeder 10 provides components to be mounted on a series of circuit boards, and discharges the waste tapes 20. Outer ends of the waste tapes 20 are respectively connected to the winders 30. In alternative embodiments, more waste tapes 20 or only one waste tape 20 may be present, with a corresponding number of winders 30.

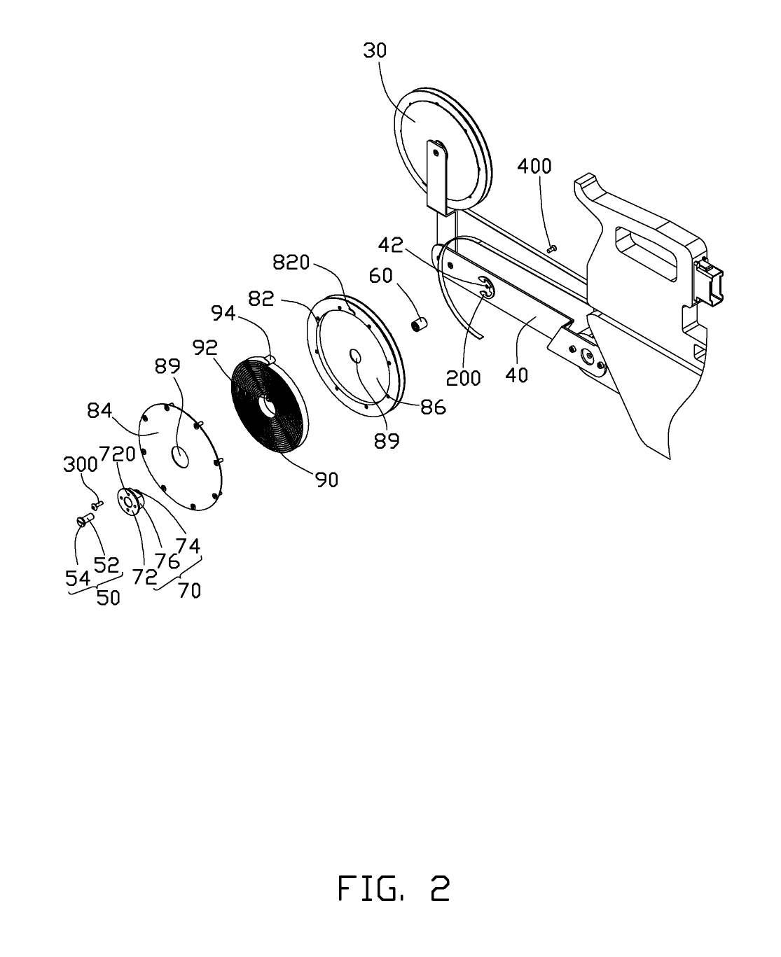

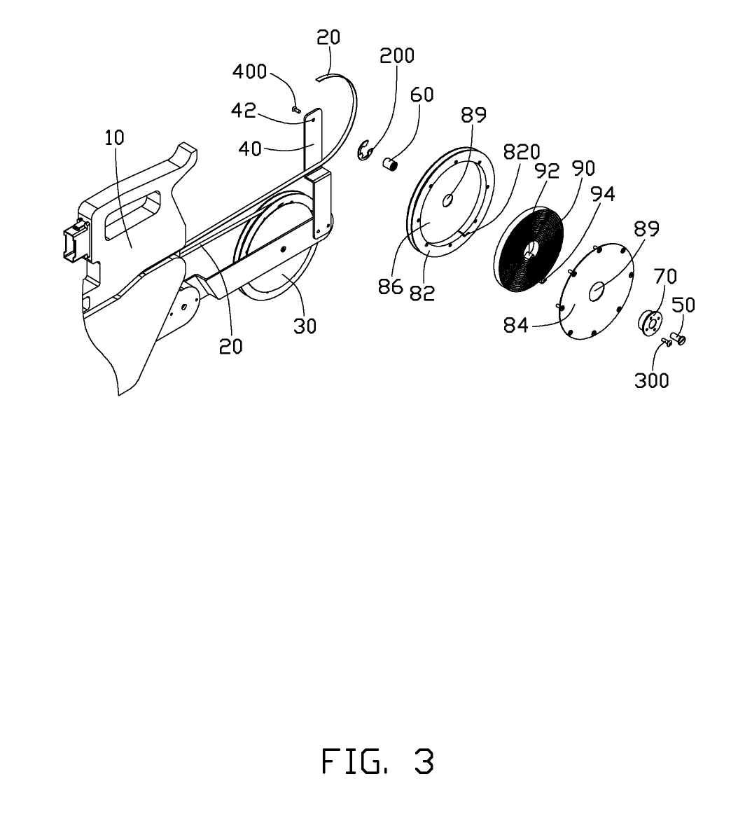

Referring also to FIG. 2 and FIG. 3, in this embodiment, the two winders 30 are the same in structure, and are set one above the other to take up the waste tapes 20 in opposite directions, one clockwise and one counterclockwise.

Each winder 30 includes a support member 40, a pivot 50, a bearing 60, a rotor 70, a wheel 80 and a coil spring 90. The pivot 50 is fixed on the support member 40 by a fastener 400. The bearing 60 is mounted around the pivot 50. The rotor 70 is mounted around the bearing 60. The wheel 80 is mounted around the rotor 70. The coil spring 90 is received in the wheel 80.

In this embodiment, the two support members 40 of the two winders 30 are connected to the feeder 10, and the two support members 40 cooperatively form a generally L-shaped profile. One support member 40 is vertical, and the other support member 40 is horizontal. The horizontal support member 40 has one end connected to the feeder 10. The vertical support member 40 has a bottom end connected to the other end of the horizontal support member 40. Each of the support members 40 defines a through hole 42 through which the fastener 400 passes to connect the pivot 50. In this embodiment, the horizontal support member 40 defines the through hole 42 at a middle portion thereof, and the vertical horizontal support member 40 defines the through hole 42 at a top end thereof.

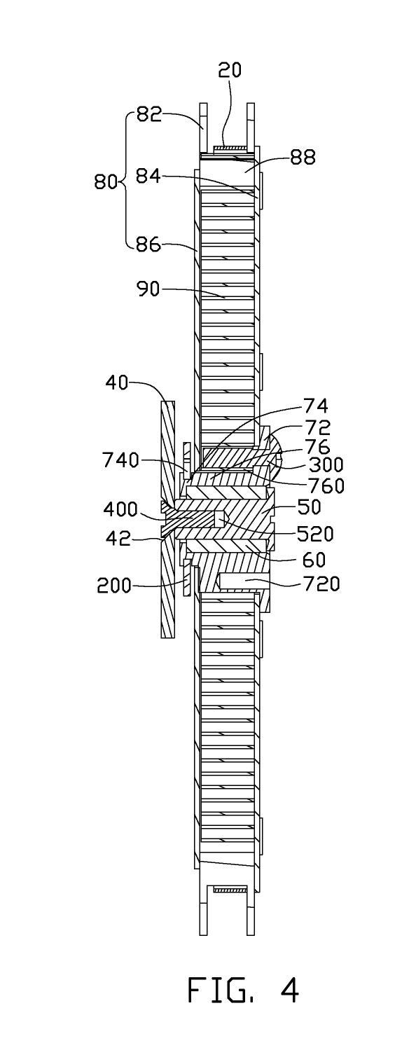

Referring to FIG. 4, the pivot 50 includes a post 52, and a head 54 formed at one end of the post 52. The head 54 has an outer diameter larger than that of the post 52. A fixing hole 520 is defined in the other end of the post 52, matching the fastener 400.

The bearing 60 is rotatably mounted on the pivot 50. An inner diameter of the bearing 60 is substantially the same as the outer diameter of the post 52 of the pivot 50, and an outer diameter of the bearing 60 is substantially the same as the outer diameter of the head 54 of the pivot 50. In this embodiment, the bearing 60 is a one-way bearing, and can only rotate along the same direction as the wheel 80.

The rotor 70 is hollow, and has an inner diameter slightly less than the outer diameter of the bearing 60. The rotor 70 is mounted around the bearing 60 by interference fitting, and can rotate with the bearing 60. The rotor 70 includes a limiting end 72, a latching end 74, and a pole 76 between the limiting end 72 and the latching end 74. An outer diameter of the limiting end 72 is larger than the outer diameter of the pole 76, and the outer diameter of the pole 76 is larger than the outer diameter of the latching end 74. A keyway 760 is defined in an outer surface of the pole 76. A cross section of the pole 76 is generally D-shaped. The latching end 74 forms an annular groove 740 in an outer surface thereof. The limiting end 72 defines a plurality of locking holes 720 in an outer periphery thereof. One of the locking holes 720 is aligned with the keyway 760 of the pole 76.

The wheel 80 is mounted around the pole 76 of the rotor 70. A thickness of the wheel 80 is slightly larger than a width of the waste tape 20. The wheel 80 includes a reel 82, a front cover 84 and a rear cover 86. The reel 82 is hollow, and has an inner diameter less than an outer diameter of each of the front cover 84 and the rear cover 86. A mounting hole 89 is defined in a central portion of each of the front cover 84 and the rear cover 86. The mounting holes 89 each have a diameter substantially the same as the outer diameter of the pole 76 of the rotor 70. When assembled, the front cover 84 and the rear cover 86 are mounted at front and rear sides of the reel 82, respectively. A central axis of the reel 82 is collinear with those of the front cover 84 and the rear cover 86. An outer periphery of each of the front cover 84 and the rear cover 86 covers inner edges of the reel 82. Screws (not labeled) extend through the front cover 84 and the rear cover 86 to engage in the reel 82, thereby assembling the wheel 80. A space 88 is defined in the wheel 80 between the front cover 84, the rear cover 86 and the reel 82, for receiving the coil spring 90. A slot 820 is defined in an outer periphery of the reel 82.

The coil spring 90 is mounted in the space 88, with an inner end 92 of the coil spring 90 connected to the rotor 70, and an outer end 94 of the coil spring 90 engaged in the slot 820 of the reel 82 of the wheel 80. The coil spring 90 from the inner end 92 to the outer end 94 is wound in a direction opposite to the direction of rotation of the wheel 80.

When assembling the winder 30, the coil spring 90 is disposed in the space 88, with the outer end 94 received in the slot 820. The pole 76 of the rotor 70 extends through the mounting hole 89 of the front cover 84, the reel 82 and the mounting hole 89 of the rear cover 86 in turn, until the latching end 74 of the rotor 70 is beyond the wheel 80. A locking ring 200 is then received in the annular groove 740 of the latching end 74 of the rotor 70 to keep the wheel 80 on the pole 76 of the rotor 70, maintaining stable rotation of the wheel 80. A pin 300 extends through one of the locking holes 720 of the limiting end 72 of the rotor 70 into the keyway 760 of the pole 76 to engage the inner end 92 of the coil spring 90, and thus the inner end 92 of the coil spring 90 is fixed on the rotor 70 and cannot rotate relative to the rotor 70. The pin 300 can be fixed on the rotor 70 by interference fitting. Alternatively, the pin 300 can be screwed in the rotor 70. In other embodiments, the pin 300 can be integrally formed on the rotor 70 as one monolithic piece.

The rotor 70 and the bearing 60 are fixed together by interference fitting. The pivot 50 is inserted in the bearing 60, with the head 54 of the pivot 50 abutting against an end surface of the bearing 60. It should be understood that an order for assembling the rotor 70, the bearing 60, the pivot 50 and the wheel 80 can be adjusted freely. The fastener 400 extends through the through hole 42 of the support member 40 and is received in the fixing hole 520 of the pivot 50. Thus, the winder 30 is assembled.

Before operation of the surface mounting apparatus 100, the bearing 60 is rotated and accordingly the rotor 70 rotates. A rotation direction of the bearing 60 is contrary to the winding direction of the coil spring 90 from the inner end 92 to the outer end 94. Since the inner end 92 of the coil spring 90 is fixed on the rotor 70, the inner end 92 of the coil spring 90 also rotates with the bearing 60, thereby tightening the coil spring 90. Since the bearing 60 is a one-way bearing, the coil spring 90 retains its tension when the bearing 60 stops rotating. A length of the waste tape 20 which can be wound by the winder 30 is mainly dependent upon the size of the coil spring 90. In one embodiment, the coil spring 90 has 22 windings and is 8 mm (millimeters) in width. The winder 30 with such coil spring 90 can provide a tension on the waste tape 20 of about 0.5˜0.6 kgf (kilogram-force), and can wind a waste tape 20 of about 6.5 m (meters) in length.

During operation of the surface mounting apparatus 100, the feeder 10 provides components to be mounted on a series of circuit boards, and thus discharges the waste tape 20 towards the winders 30. Thereupon, the wheel 80 of each winder 30 rotates relative to the rotor 70, to wind the waste tape 20 on the wheel 80. During rotation of the wheel 80, the outer end 94 of the coil spring 90 rotates with the wheel 80 to provide elastic force applied to the wheel 80 to maintain the tension on the waste tape 20. Accordingly, the components can be mounted precisely, and an efficiency of the surface mounting apparatus 100 is improved. In addition, the winder 30 requires no electric power, which is energy saving and environmentally responsible.

It is to be understood, however, that even though numerous characteristics and advantages of certain embodiments have been set forth in the foregoing description, together with details of the structures and functions of the embodiments, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A surface mounting apparatus, comprising:
a winder comprising a pivot, a wheel rotatably mounted around the pivot, and a coil spring disposed between the pivot and the wheel, an outer end of the coil spring being connected to the wheel to rotate with the wheel, and an inner end of the coil spring being static relative to the pivot during rotation of the wheel;
a waste tape connected to the wheel of the winder; and
a feeder for discharging the waste tape towards the winder.

2. The surface mounting apparatus of claim 1, further comprising a one-way bearing mounted between the coil spring and the pivot, the one-way bearing being rotatable relative to the pivot in a direction which is contrary to a winding direction of the coil spring from the inner end to the outer end.

3. The surface mounting apparatus of claim 2, further comprising a rotor mounted between the one-way bearing and the coil spring, the rotor being fixed with the bearing to rotate with the bearing.

4. The surface mounting apparatus of claim 3, wherein the one-way bearing is interference fitted in the rotor.

5. The surface mounting apparatus of claim 3, wherein the inner end of the coil spring is connected to the rotor.

6. The surface mounting apparatus of claim 5, wherein the rotor comprises a pole and a limiting end formed at one end of the pole, a diameter of the pole is less than that of the limiting end, the coil spring is mounted around the pole of the rotor, and the limiting end of the rotor abuts against the wheel.

7. The surface mounting apparatus of claim 6, wherein the pole of the rotor defines a keyway, a cross section of the pole is generally D-shaped, a locking hole is defined in the limiting end corresponding to the keyway of the rotor, a pin extends through the locking hole of the limiting end into the keyway, and the inner end of the coil spring engages with the pin.

8. The surface mounting apparatus of claim 6, wherein the pin is interference fitted in the locking hole of the limiting end of the rotor.

9. The surface mounting apparatus of claim 6, wherein the pin is screwed in the locking hole of the limiting end of the rotor.

10. The surface mounting apparatus of claim 6, further comprising a locking ring, wherein the rotor further comprises a latching end formed at the other end of the pole, an annular groove is defined in the latching end, and the locking ring is received in the annular groove to limit the wheel on the pole of the rotor.

11. A winder for a surface mounting apparatus, the winder comprising:
a pivot;
a wheel rotatably mounted around the pivot; and
a coil spring disposed between the pivot and the wheel, an outer end of the coil spring being connected to the wheel to rotate with the wheel, and an inner end of the coil spring being static relative to the pivot during rotation of the wheel.

12. The winder of claim 11, further comprising a one-way bearing mounted between the coil spring and the pivot, the one-way bearing being rotatable relative to the pivot in a direction which is contrary to a winding direction of the coil spring from the inner end to the outer end.

13. The winder of claim 12, further comprising a rotor mounted between the one-way bearing and the coil spring, the rotor being fixed with the bearing to rotate with the bearing.

14. The winder of claim 13, wherein the one-way bearing is interference fitted in the rotor.

15. The winder of claim 13, wherein the inner end of the coil spring is connected to the rotor.

16. The winder of claim 15, wherein the rotor comprises a pole and a limiting end formed at one end of the pole, a diameter of the pole is less than that of the limiting end, the coil spring is mounted around the pole of the rotor, and the limiting end of the rotor abuts against the wheel.

17. The winder of claim 16, wherein the pole of the rotor defines a keyway, a cross section of the pole is D-shaped, a locking hole is defined in the limiting end corresponding to the keyway of the rotor, a pin extends through the locking hole of the limiting end into the keyway, and the inner end of the coil spring engages with the pin.

18. The winder of claim 16, wherein the pin is interference fitted in the locking hole of the limiting end of the rotor.

19. The winder of claim 16, wherein the pin is screwed in the locking hole of the limiting end of the rotor.

20. The winder of claim 16, further comprising a locking ring, wherein the rotor further comprises a latching end formed at the other end of the pole, an annular groove is defined in the latching end, and the locking ring is received in the annular groove to limit the wheel on the pole of the rotor.
